(19) United States
(12) Patent Application Publication
(10) Pub. No.: US 2020/0011817 A1
(43) Pub. Date: Jan. 9, 2020

(54) METHOD FOR OBTAINING A TWO-DIMENTIONAL J-RESOLVED NMR SPECTRUM AGAINST INHOMOGENEOUS MAGNETIC FIELD APPLIED ALONG A SINGLE DIRECTION

(71) Applicant: Xiamen University, Xiamen (CN)

(72) Inventors: Zhong CHEN, Xiamen (CN); Haolin ZHAN, Xiamen (CN); Qimiao YE, Xiamen (CN); Jian YANG, Xiamen (CN); Hong LI, Xiamen (CN); Yuqing HUANG, Xiamen (CN); Shuhui CAI, Xiamen (CN)

(21) Appl. No.: 16/571,601

(22) Filed: Sep. 16, 2019

Related U.S. Application Data
(63) Continuation of application No. PCT/CN2017/115473, filed on Dec. 11, 2017.

(30) Foreign Application Priority Data
Mar. 15, 2017 (CN) 201710153235.8

(51) Int. Cl. G01N 24/08; G01R 33/46; G06F 17/15

(52) U.S. Cl. CPC G01N 24/08; G01R 33/4633; G06F 17/156; G01R 33/4616

(57) ABSTRACT

The present disclosure provides a method for ultrafastly obtaining a two-dimensional J-resolved NMR spectrum with a high-resolution against an inhomogeneous magnetic field. The method utilizes the selective excitation module and the reunion sampling module jointly, which breaks through the limitations of existing methods for obtaining the two-dimensional J-resolved NMR spectrum and effectively eliminates an influence of the inhomogeneous magnetic field along an encoding direction. At the same time, an inhomogeneous magnetic field along x and y directions is theoretically eliminated by a slow rotation of the sample. As a consequence, a two-dimensional J-resolved NMR spectrum with a high resolution is obtained by a single-scanning sampling under the inhomogeneous magnetic field, thus significantly shortening experimental duration and expanding application fields of the two-dimensional J-resolved NMR spectrum. The present disclosure further provides a method using multi-band sampling, which is used to obtain J-resolved NMR spectrum with improved signal-to-noise ratio.

### RELATED APPLICATIONS

This application is a continuation of and claims priority to PCT Patent Application PCT/CN2017/115473, filed on Dec. 11, 2017, which claims priority to Chinese Patent Application 201710153235.8, filed on Mar. 15, 2017. PCT Patent Application PCT/CN2017/115473 and Chinese Patent Application 201710153235.8 are incorporated herein by reference.

### FIELD OF THE DISCLOSURE

The present disclosure relates to a Nuclear Magnetic Resonance (NMR) spectroscopy technique for detecting molecular structure information, in particular to a method for ultrafastly obtaining a two-dimensional J-resolved spectrum against an inhomogeneous magnetic field applied along a single direction.

### BACKGROUND OF THE DISCLOSURE

In recent decades, since the NMR spectroscopy technique has the advantage of providing non-destructive and non-invasive detection, the NMR spectroscopy technique has been widely applied in various areas, such as biology, chemistry, physics, pharmaceutical and material science. A scholar, Jeener, proposed a concept of two-dimensional spectrum on the basis of one-dimensional spectroscopy in 1971, and the NMR spectroscopy technique has been extended from one-dimensional spectroscopy to two-dimensional spectroscopy. In constant detection using the NMR spectroscopy technique, the two-dimensional spectrum overcomes the problems of spectral congestion and spectral peak identification often appearing in the one-dimensional hydrogen spectroscopy, and may transmit more molecular structure information and dynamic information. A two-dimensional J-resolved NMR spectrum has characteristics for indicating chemical shift information of atomic nucleus by a direct dimension and indicating scalar coupling splitting mode and coupling constants among the atomic nucleus by an indirect dimension, which has been frequently applied to composition analysis and molecular structural identification of a sample, thus being regarded as an important NMR analytical method. The existing method for obtaining the two-dimensional J-resolved NMR spectrum is based on the sequence based on a spin-echo module proposed by Richard R. Ernst in 1976. Although the existing method for obtaining the two-dimensional J-resolved NMR spectrum provides a common method for obtaining chemical shifts and coupling constants of the atomic nucleus, there remain limitations in practical application. Firstly, since the existing method for obtaining the two-dimensional J-resolved NMR spectrum comprises a two-dimensional sampling, it is time-consuming to ensure a resolution of the spectrum. The aforementioned problem restricts the application of the existing method in the field, by way of example, restricting real-time analysing of the chemical reaction, and restricting the development and application of the existing method in multi-dimensional spectroscopy. Secondly, the obtaining of the existing two-dimensional J-resolved NMR spectrum is restricted by a homogeneous performance of a magnetic field, and an ideal two-dimensional J-resolved NMR spectrum can only be obtained in a homogeneous magnetic field. In practical application, even for homogeneous solution samples, it is necessary to generate a uniform magnetic field on the homogeneous solution samples for detection to obtain a satisfactory magnetic field, which is complicated and time-consuming. However, for heterogeneous samples, such as viscous samples and biological tissue samples, the intrinsic susceptibility variations cause high field inhomogeneity, rendering the implementation of high field homogeneity difficult, if not impossible. The aforementioned problem also limits the application range of the existing two dimensional J-resolved NMR spectrum.

### BRIEF SUMMARY OF THE DISCLOSURE

The main technical problem to be solved by the present disclosure is to provide a method for obtaining a two-dimensional J-resolved NMR spectrum against an inhomogeneous magnetic field. The two-dimensional J-resolved NMR spectrum with high resolution can be quickly obtained merely by single scanning. The method for obtaining the two-dimensional J-resolved NMR spectrum through single-scanning comprises a method of single-band sampling. On the aforementioned basis, the present disclosure further provides a method for efficiently improving the signal-to-noise ratio of the aforementioned J-resolved NMR spectrum through multi-band sampling, and greatly improving a signal-to-noise ratio performance of the spectrum by a multi-band sampling excited on the basis of a polychromatic pulse. The present disclosure overcomes the shortcomings of existing methods for obtaining the two-dimensional J-resolved NMR spectrum in practical application, thus playing a significant role in extending the application range of the two-dimensional J-resolved NMR spectrum and detecting the chemical structures of samples.

In order to solve the aforementioned technical problems, the present disclosure provides a first method for ultrafastly obtaining a two-dimensional J-resolved NMR spectrum against an inhomogeneous magnetic field (especially a large, linear, inhomogeneous magnetic field along a single direction) applied along a single direction, comprising the following steps:

step 1) packing a test sample, and sampling the test sample by regular one-dimensional hydrogen spectrum:

sending a sample tube containing a test sample into a testing cavity of a NMR spectrometer, and applying a sequence of regular one-dimensional hydrogen spectrum to collect a one-dimensional hydrogen spectrum of the test sample;

the sequence of the regular one-dimensional hydrogen spectrum is a single-pulse sequence integrated in the NMR spectrometer and comprises a non-selective radio frequency pulse and a signal sampling period;

step 2) measuring a duration of a π/2 non-selective radio frequency pulse:

using the single-pulse sequence, measuring a duration of a π/2 non-selective radio frequency pulse required for exciting the test sample;

step 3) introducing pulse sequence and setting experimental parameters for sampling:

introducing a designed NMR pulse sequence into the NMR spectrometer, wherein the designed NMR pulse sequence comprises a selective excitation module and a reunion sampling module, setting experimental parameters of the selective excitation module and the reunion sampling module, and sampling data associated with the test sample based on a single-band sampling; and

step 4) post-processing the data:

after sampling the data, using post-processing codes, and carrying out data processing to obtain the two-dimensional J-resolved NMR spectrum against the inhomogeneous magnetic field applied along the single direction,

wherein the steps of the data processing are as follows: (a) collecting odd-numbered data of the data by an odd-numbered sampling module and even-numbered data of the data by an even-numbered sampling module of different quantum levels, separating the odd-numbered data and the even-numbered data in data processing, and separately extracting the odd-numbered data or the even-numbered data for post-processing; and (b) carrying out a two-dimensional Fourier transform on the odd-numbered data to obtain the two-dimensional J-resolved NMR spectrum against the inhomogeneous magnetic field applied along the single direction.

In a preferred embodiment, in step 3), the selective excitation module comprises a π/2 selective Gaussian pulse, a single directional encoding gradient simultaneously applied with the π/2 selective Gaussian pulse, and two compensation gradients;

In a preferred embodiment, a direction applied by the single directional encoding gradient and the two compensation gradients is the same as an inhomogeneous direction of the inhomogeneous magnetic field in an actual test, and the selective excitation module is configured to selectively invert a longitudinal magnetization vector of the test sample into a transverse x-y plane, and to associate a procession frequency of a selected atomic nucleus with a spatial position of the selected atomic nucleus;

In a preferred embodiment, the reunion sampling module comprises a sampling module repeated 2N times, each time of the 2N times comprises a sampling time TD, which effect simultaneously with the single directional encoding gradient, and a non-selective radio frequency pulse with an angle of 180°; and the reunion sampling module is configured to decode spectrum information encoded in the selective excitation module, so as to read out the two-dimensional J-resolved NMR spectrum against the inhomogeneous magnetic field applied along the single direction.

In a preferred embodiment, the experimental parameters comprise a duration of the π/2 non-selective radio frequency pulse, a pulse duration and a radio frequency power of the π/2 selective Gaussian pulse, a spectral width by a direct dimension, an intensity of the single directional encoding gradient, a first intensity and a second intensity of the two compensation gradients, durations of the two compensation gradients, a sampling time of each sampling of the reunion sampling module, an intensity of a decoding gradient, a repeated times 2N of the reunion sampling module, and sampling points, and the single directional encoding gradient is applied simultaneously with the π/2 selective Gaussian pulse.

The present disclosure further provides a second method for obtaining a two-dimensional J-resolved NMR spectrum against an inhomogeneous magnetic field applied in a single direction, which is obtained by multi-band sampling excited on the basis of a polychromatic pulse, so that the signal-to-noise ratio of the J-resolved NMR spectrum obtained is greatly improved. The detailed steps are generally the same as the aforementioned method based on the single-band sampling, the specific differences are as below:

Step 2) of the second method further comprises, generating a polychromatic pulse by a Fourier encoding technique, and generating a pulse duration and a radio frequency power of the polychromatic pulse according to an experimental requirement to obtain multi-band signals;

In step 3) of the second method, the selective excitation module comprises the polychromatic pulse, a single directional encoding gradient simultaneously applied with the polychromatic pulse, and two compensation gradients;

A direction applied by the single directional encoding gradient and the two compensation gradients is the same as an inhomogeneous direction of the inhomogeneous magnetic field in an actual test, and the selective excitation module is configured to selectively invert a longitudinal magnetization vector of the test sample into a transverse x-y plane, and to associate a procession frequency of a selected atomic nucleus with a spatial position of the selected atomic nucleus;

In step 4) of the second method, after sampling the data, decoding the multi-band signals by the Fourier encoding technique in step 2) to obtain decoded signals before using the data post-processing codes and carrying out a data processing, and, after carrying out the data processing, calibrating and superimposing the decoded signals to obtain the two-dimensional J-resolved NMR spectrum against the inhomogeneous magnetic field applied along the single direction.

Compared to the existing techniques, the technical solution of the present disclosure has the following advantages:

1. The present disclosure provides a method for obtaining a NMR two-dimensional J-resolved spectrum against an interference of an inhomogeneous magnetic field based on a single-band sampling. The method utilizes the selective excitation module and the reunion sampling module jointly, which breaks through the limitations of the existing methods for obtaining the two-dimensional J-resolved NMR spectrum, and effectively eliminates an influence of the inhomogeneous magnetic field along an encoding direction (z direction). At the same time, an inhomogeneous magnetic field along x and y directions is theoretically eliminated by a slow rotation of the sample. As a consequence, a two-dimensional J-resolved NMR spectrum with a high resolution is obtained by a single-scanning sampling under the inhomogeneous magnetic field, thus significantly shortening the experimental duration and expanding the application fields of the two-dimensional J-resolved NMR spectrum. In addition, the method is applicable to a regular NMR spectrometer, without any extra hardware equipment and any extra sample preprocessing, the method is simple in operation, and the method offers an important means for rapidly obtaining a two-dimensional J-resolved NMR spectrum of complex organic sample and biological tissue sample.

2. On the basis of the method using the single-band sampling as illustrated in the 1st advantage, the present disclosure provides a method using multi-band sampling, which is used to obtain J-resolved NMR spectrum with an improved signal-to-noise ratio. The signal-to-noise ratio performance of the spectrum is significantly improved by means of the multi-band sampling exited on the basis of polychromatic pulse. In theory, the signal-to-noise ratio may be improved N times by sampling N times.

3. The present disclosure provides the method for ultrafastly obtaining a two-dimensional J-resolved NMR spectrum against an interference of an inhomogeneous magnetic field. The selective excitation module encodes spectral information by associating a procession frequency of a selected atomic nucleus with a spatial position of the selected atomic nucleus. The reunion sampling module decodes the spectrum information encoded in the selective excitation module, and ensures the reunion of chemical shift effect in a one-dimensional signal evolution process, merely retaining the J-coupling effect; the other dimension signal comprises the chemical shift information according to the spatial position. As a result, one dimension in the obtained two-dimensional J-resolved NMR spectrum indicates J-coupling information of the coupling relation between the atomic nucleus, and the other dimension indicates the chemical shift information of the nucleus under different chemical environments.

4. The present disclosure provides a method for ultrafastly obtaining a two-dimensional J-resolved NMR spectrum against an interference of an inhomogeneous magnetic field. The combination effect of the selective excitation module and the reunion sampling module in step 3) achieves the effect of obtaining signals from different evolution times by a single experimental sampling. Thus the two-dimensional J-resolved NMR spectrum may be obtained by only single scanning, and the experimental duration is dramatically shortened.

### BRIEF DESCRIPTION OF THE DRAWING

FIG. 1 illustrates a pulse sequence diagram of two-dimensional J-resolved NMR spectrum in an ultrafast manner against an inhomogeneous magnetic field of the present disclosure. As illustrated in FIG. 1, the black hollow rectangular bar denotes a non-selective π radio frequency pulse, the Gaussian-shaped bar denotes a π/2 selective Gaussian radio frequency pulse (single-band sampling) or a polychromatic pulse (multi-band sampling), the waveform Sinc indicates a sampling process having a sampling duration TD, the solid rectangle bar indicates an encoding gradient GE, the straight line filled bar and inclined line filled bar respectively indicates compensation gradients GP1, GP2, and the horizontal hollow bar indicates a decoding gradient GD.

FIG. 2 illustrates a regular one-dimensional hydrogen spectrum of a solution sample of ethyl 3-bromopropionate dissolved in DMSO-d₆ under an inhomogeneous magnetic field obviously along the z axis and with a linewidth of about 900 Hz.

FIG. 3 illustrates a two-dimensional J-resolved NMR spectrum of a solution sample of ethyl 3-bromopropionate in an ultrafast manner based on a single-band sampling under an inhomogeneous magnetic field, and the entire experimental duration is about 4 s.

FIG. 4 is obtained by the projections along the J-coupling dimension at all chemical shifts in FIG. 3, wherein 1 to 4 denotes the scalar coupling splitting mode and corresponding coupling constants for each chemical shift at approximately 4.2, 3.7, 3.0, and 1.3 ppm, respectively.

FIG. 5 is the experimental result of a multi-band sampling excited by a polychromatic pulses proposed by the present disclosure (taking double-band sampling as an example). The sample used in the experiment is the solution sample of n-propanol dissolved in D20. FIG. 5(a) shows the change of an effective sample length for the double-band sampling compared to the single-band sampling. As illustrated in FIG. 5(a), the effective sample length of the double-band sampling is twice that of the single-band sampling; thus the signal-to-noise ratio of the double-band sampling is theoretically improved twice. FIG. 5(b) and FIG. 5(c) show the two-dimensional J-resolved spectra and the corresponding projecting spectra along the chemical shift dimension, obtained by decoding from two bands, respectively. FIG. 5(d) shows a J-resolved spectrum with a twice signal-to-noise ratio and the corresponding projecting spectrum along the chemical shift dimension, after the superimposed calibration of the two-band signals. FIG. 5(e) shows a two-dimensional J-resolved spectrum by single-band sampling and the corresponding projecting spectrum along the chemical shift dimension without polychromatic pulse excitation as a reference.

### DETAILED DESCRIPTION OF THE EMBODIMENTS

The disclosure is further described with the combination of the accompanying drawings and the detailed embodiments.

The present disclosure provides a method for quickly obtaining a two-dimensional J-resolved spectrum of a complex organic sample and a biological tissue sample with a high resolution against an interference of an inhomogeneous magnetic field (especially against a large linear inhomogeneous magnetic field along a single direction). The method is simple in operation, without any preprocessing for any sample, and is applicable to all types of regular NMR spectrometer, without any extra hardware equipment.

### Embodiment 1

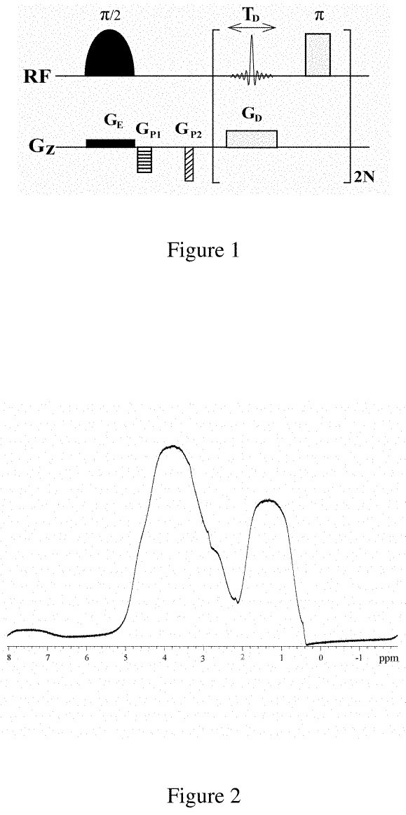

Referring to FIGS. 1-3, the present disclosure provides a method for ultrafastly obtaining a two-dimensional J-resolved NMR spectrum against an interference of an inhomogeneous magnetic field based on a single-band sampling. The steps of the specific process are listed as follows:

Step 1) packing a test sample, and sampling the test sample by regular one-dimensional hydrogen spectrum

placing a test sample is into a standard 5 mm sample tube (having an outer diameter of 5 mm), and sending the sample tube into a testing cavity of a nuclear magnetic spectrometer. Then, a sequence of the regular one-dimensional hydrogen spectrum is applied to collect the one-dimensional hydrogen spectrum of the test sample to obtain the signal linewidth information. The sequence of the regular one-dimensional hydrogen spectrum is a single-pulse sequence integrated in the NMR spectrometer and comprises a non-selective radio frequency pulse and a signal sampling period. This step can obtain the spectral width and magnetic field inhomogeneity information after placing the test sample and provides reference for the parameters to be set in the following steps. At the same time, in order to verify the performance of the method against the interference of the inhomogeneous magnetic field applied along the single direction, a magnetic field is artificially deshimmed in the method of single-band sampling.

Step 2) measuring a duration of a π/2 non-selective radio frequency pulse

Measuring a duration of a π/2 non-selective radio frequency pulse required to excite the test sample and a pulse duration and a radio frequency power of a π/2 selective Gaussian pulse. Using the single-pulse sequence of step 1, setting a serial of pulse action durations for sampling the corresponding signals; measuring the respective pulse duration when the magnetization vector is inverted from a longitudinal direction to an x-y plane, that is, the duration of the π/2 non-selective radio frequency pulse. The duration of the π non-selective radio frequency pulse is twice the duration of the π/2 non-selective radio frequency pulse. Similarly, for the single-band sampling technique, the pulse type of the single-pulse sequence is changed to a Gaussian pulse. The above procedures are repeated to determine the pulse duration and the radio frequency power of the π/2 selective Gaussian pulse required to excite the test sample;

Step 3) introducing pulse sequence and setting experimental parameters for sampling:

Introducing a designed NMR pulse sequence into the NMR spectrometer (as illustrated in FIG. 1), and the designed NMR pulse sequence comprises a selective excitation module and a reunion sampling module. The selective excitation module comprises a π/2 selective Gaussian pulse, a single directional encoding gradient applied simultaneously with the π/2 selective Gaussian pulse, and two compensation gradients. The selective excitation module is configured to selectively invert a longitudinal magnetization vector of the test sample into a transverse x-y plane, and to associate a procession frequency of a selected atomic nucleus with a spatial position of the selected atomic nucleus.

The reunion sampling module comprises a sampling module repeated 2N times, each time of the 2N times comprises a sampling time TD which effects simultaneously with the single directional encoding gradient, and a non-selective radio frequency pulse with an angle of 180°; the reunion sampling module is configured to decode spectrum information encoded in the selective excitation module, so as to read out the two-dimensional J-resolved NMR spectrum with a high resolution.

At the same time, the experimental parameters of the selective excitation module and a reunion sampling module are set accordingly. The experimental parameters include a duration of the π/2 non-selective radio frequency pulse, a pulse duration and a radio frequency power of the π/2 selective Gaussian pulse, a spectral width SW of a direct dimension, an intensity GE of the encoding gradient applied simultaneously with the selective Gaussian pulse, and intensities GP1 and GP2 of the compensation gradients and action durations of the compensation gradients, a duration TD of each sampling of the sampling module, an intensity GD of a decoding gradient, a repeated times 2N of the sampling module, and sampling points np. Then the data sampling is directly carried out.

Step 4) post-processing the data

After sampling the data, using data post-processing codes, carrying out a data processing, the main processes of the data processing are given as follows: (a) collecting odd-numbered data by an odd-numbered sampling module and even-numbered data by an even-numbered sampling module of different quantum levels, separating the odd-numbered data and the even-numbered data in data processing, separately extracting the odd-numbered data or the even-numbered data for post-processing; (b) carrying out a two-dimensional Fourier transform on the odd-numbered data and therefore to obtain a piece of the two-dimensional J-resolved NMR spectrum with a high resolution against the interference of the inhomogeneous magnetic field applied along the single direction.

### Embodiment 2

On the basis of Embodiment 1, the present disclosure further extends to a method of obtaining two-dimensional J-resolved NMR spectrum with a greatly improved signal-to-noise ratio based on a multi-band sampling excited by a polychromatic pulse. The specific steps are identical to the aforementioned method based on a single-band sampling, and comprises the following steps:

Step 1) packing a test sample, and sampling the test sample by regular one-dimensional hydrogen spectrum

Sending a sample tube containing a test sample into a testing cavity of a NMR spectrometer. A sequence of the regular one-dimensional hydrogen spectrum is applied to collect the regular one-dimensional hydrogen spectrum of the test sample;

The sequence of the regular one-dimensional hydrogen spectrum is a single-pulse sequence integrated in the NMR spectrometer and comprises a non-selective radio frequency pulse and a signal sampling period;

Step 2) measuring a duration of a π/2 non-selective radio frequency pulse

Measuring a duration of a π/2 non-selective radio frequency pulse required to excite the sample by using the single-pulse sequence;

Step 3) introducing pulse sequence and setting experimental parameters for sampling

Introducing a designed NMR pulse sequence into the NMR spectrometer, wherein the designed NMR pulse sequence comprises a selective excitation module and a reunion sampling module; setting experimental parameters of the selective excitation module and the reunion sampling module; and sampling data of the test sample;

The reunion sampling module comprises a sampling module repeated 2N times, each of the 2N times comprises a sampling time TD which effects simultaneously with the single directional encoding gradient, and a non-selective radio frequency pulse with an angle of 180°.

Step 4) post-processing the data

After sampling the data, using data post-processing codes, carrying out data processing to obtain the two-dimensional J-resolved NMR spectrum against the interference of the inhomogeneous magnetic field along a single direction;

the steps of the data processing are as follows: (a) collecting odd-numbered data by an odd-numbered sampling module and even-numbered data by an even-numbered sampling module of different quantum levels, separating the odd-numbered data and the even-numbered data in data processing, and separately extracting the odd-numbered data or the even-numbered data for post-processing; and (b) carrying out a two-dimensional Fourier transform on the odd-numbered data to obtain the two-dimensional J-resolved NMR spectrum with a high resolution against the interference of the inhomogeneous magnetic field along a single direction.

The differences between Embodiment 1 and Embodiment 2 are listed as follows:

Step 2) of Embodiment 2 further comprises, generating a polychromatic pulse by a Fourier encoding technique, and generating a pulse duration and a radio frequency power of the polychromatic pulse according to an experimental requirement to obtain multi-band signals.

In step 3) of Embodiment 2, the selective excitation module comprises the polychromatic pulse, a single directional encoding gradient simultaneously applied with the polychromatic pulse, and two compensation gradients;

A direction applied by the unidirectional encoding gradient and compensation gradients are the same as an inhomogeneous direction of the inhomogeneous magnetic field in an actual test; the selective excitation module is configured to selectively invert a longitudinal magnetization vector of the test sample into a transverse x-y plane, and to associate a procession frequency of a selected atomic nucleus with a spatial position of the selected atomic nucleus;

In step 4) of the Embodiment 2, after sampling the data, firstly decoding the multi-band signals by the Fourier encoding technique in step 2) to obtain decoded signals, using data post-processing codes, carrying out the data processing, and then calibrating and superimposing the decoded signals to obtain the two-dimensional J-resolved NMR spectrum with the high signal-noise ratio against the interference of the inhomogeneous magnetic field along a single direction.

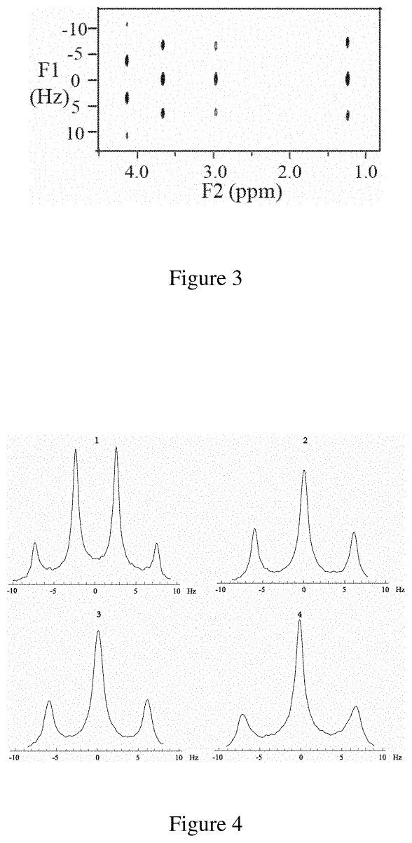

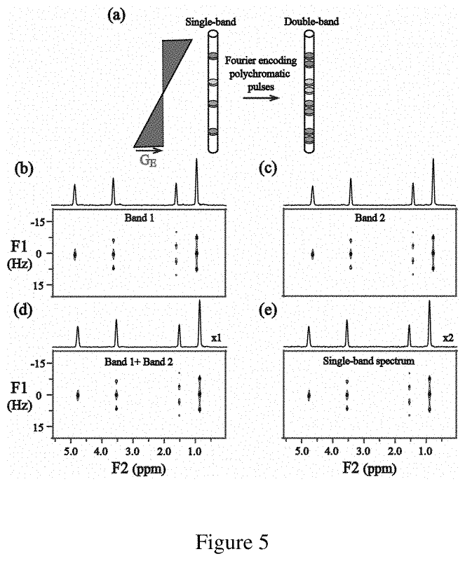

The test samples in the aforementioned embodiments are a solution sample of ethyl 3-bromopropionate dissolved in DMSO-d₆, and a solution sample of propanol dissolved in D20. The NMR spectrometer in the aforementioned embodiment is a Varian 500 MHz NMR spectrometer. In order to verify the performance of the method against the interference of the inhomogeneous magnetic field applied along the single direction, a magnetic field is artificially deflected in the method of single-band sampling. According to the operation procedure proposed by the disclosure, firstly packing a test sample, measuring a duration of a π/2 non-selective radio frequency pulse required by the single-pulse sequence, then introducing the designed NMR pulse sequence illustrated in FIG. 1, and setting the corresponding experimental parameters. Referring to the test samples used in the embodiments, the experimental parameters of the method of single-band sampling are set as follows: the duration of π non-selective radio frequency pulse is 30.3 s; the pulse duration and the radio frequency power of the π/2 selective Gaussian pulse are respectively 96.2 ms and −6 dB; the spectral width SW of the direct dimension=25000 Hz, the intensity GE of the encoding gradient applied simultaneously with the selective Gaussian pulse is 0.28 G/cm, the compensating gradient GP1 is −13.5 G/cm and its action duration is 1.0 ms; the compensating gradient GP2 is −12.1 G/cm and its action duration is 1.5 ms, the sampling duration TD of each sampling of the sampling module=14.0 ms, the intensity of the decoding gradient GD=3.6 G/cm, the repeated number 2N of the sampling module=280, the sampling points np=196000, and a waiting time of the single-pulse sequence is 1 s. A total experimental duration is about 5 s. After sampling original data, processing the original data according to the aforementioned post-processing steps to obtain the two dimensional J-resolved NMR spectrum illustrated in FIG. 3, wherein a vertical axis of the two dimensional J-resolved NMR spectrum indicates the scalar coupling splitting mode and the coupling constants of the test sample (molecule), and the horizontal axis of the two dimensional J-resolved NMR spectrum indicates chemical shifts of the nucleus under different chemical environments. Therefore, FIG. 3 can be used as an important basis for composition analysis and structural identification of the test sample. The experimental parameters of the method of multi-band sampling are set as follows: the duration of π non-selective radio frequency pulse is 20.45 s; the pulse duration and the radio frequency power of the π/2 polychromatic pulse are respectively 120.0 ms and −10 dB; the spectral width SW of the direct dimension=25000 Hz, the intensity GE of the encoding gradient applied simultaneously with the selective Gaussian pulse is 0.42 G/cm, the compensating gradient GP1 is −25.3 G/cm and its action duration is 1.0 ms; the compensating gradient GP2 is −11.5 G/cm and its action duration is 1.5 ms, the sampling duration TD of each sampling of the sampling module=9.0 ms, the intensity of the decoding gradient GD=3.8 G/cm, the repetition number 2N of the sampling module=120, the sampling points np=54000, and a waiting time of the pulse sequence is 6 s. A total experimental duration is about 12 s. After sampling original data, processing the original data sampled by the method of multi-band sampling according to the aforementioned post-processing steps. The experimental result is illustrated in FIG. 5.

The above description is only a preferred embodiment of the present disclosure, and the scope of the present disclosure is not limited in this embodiment. That is, equivalent changes and modifications made in the scope of the disclosure and the specification contents should remain within the scope of the present disclosure.

### INDUSTRIAL APPLICABILITY

The present disclosure provides a method for ultrafastly obtaining two-dimensional J-resolved NMR spectrum with a high resolution against an inhomogeneous magnetic field. The method utilizes the selective excitation module and the reunion sampling module jointly, which breaks through the limitations of the existing methods for obtaining the two-dimensional J-resolved NMR spectrum, and effectively eliminates an influence of the inhomogeneous magnetic field along an encoding direction (z direction). At the same time, an inhomogeneous magnetic field along x and y directions is theoretically eliminated by a slow rotation of the sample. As a consequence, a two-dimensional J-resolved NMR spectrum with a high resolution is obtained by a single-scanning sampling under the inhomogeneous magnetic field, thus significantly shortening the experimental duration and expanding the application fields of the two-dimensional J-resolved NMR spectrum. Based on the method using the single-band sampling, the present disclosure further provides a method using multi-band sampling, which is used to obtain J-resolved NMR spectrum with an improved signal-to-noise ratio.

What is claimed is:

1. A method for obtaining a two-dimensional J-resolved Nuclear Magnetic Resonance (NMR) spectrum against an inhomogeneous magnetic field applied along a single direction, wherein the method comprises the following steps:
1) sending a sample tube containing a test sample into a testing cavity of a NMR spectrometer, and applying a sequence of regular one-dimensional hydrogen spectrum to collect a one-dimensional hydrogen spectrum of the test sample, wherein the sequence of the regular one-dimensional hydrogen spectrum is a single-pulse sequence integrated in the NMR spectrometer and comprises a non-selective radio frequency pulse and a signal sampling period;
2) using the single-pulse sequence, measuring a duration of a π/2 non-selective radio frequency pulse required for exciting the test sample;
3) introducing a designed NMR pulse sequence into the NMR spectrometer, wherein the designed NMR pulse sequence comprises a selective excitation module and a reunion sampling module, setting experimental parameters of the selective excitation module and the reunion sampling module, and sampling data associated with the test sample based on a single-band sampling; and
4) after sampling the data, using data post-processing codes, and carrying out data processing to obtain the two-dimensional J-resolved NMR spectrum against the inhomogeneous magnetic field applied along the single direction,
wherein the steps of the data processing are as follows:
(a) collecting odd-numbered data of the data by an odd-numbered sampling module and even-numbered data of the data by an even-numbered sampling module of different quantum levels, separating the odd-numbered data and the even-numbered data in data processing, and separately extracting the odd-numbered data or the even-numbered data for post-processing; and
(b) carrying out a two-dimensional Fourier transform on the odd-numbered data to obtain a piece of the two-dimensional J-resolved NMR spectrum against the inhomogeneous magnetic field applied along the single direction.

2. The method according to claim 1, wherein:
in step 3), the selective excitation module comprises a π/2 selective Gaussian pulse, a single directional encoding gradient simultaneously applied with the π/2 selective Gaussian pulse, and two compensation gradients.

3. The method according to claim 2, wherein:
a direction applied by the single directional encoding gradient and the two compensation gradients is the same as an inhomogeneous direction of the inhomogeneous magnetic field in an actual test, and
the selective excitation module is configured to selectively invert a longitudinal magnetization vector of the test sample into a transverse x-y plane, and to associate a procession frequency of a selected atomic nucleus with a spatial position of the selected atomic nucleus.

4. The method according to claim 2, wherein:
the reunion sampling module comprises a sampling module repeated 2N times,
each time of the 2N times comprises a sampling time, which effect simultaneously with the single directional encoding gradient, and a non-selective radio frequency pulse with an angle of 180°, and
the reunion sampling module is configured to decode spectrum information encoded in the selective excitation module, so as to read out a piece of the two-dimensional J-resolved NMR spectrum against the inhomogeneous magnetic field applied along the single direction.

5. The method according to claim 2, wherein:
the experimental parameters comprise a duration of the π/2 non-selective radio frequency pulse, a pulse duration and a radio frequency power of the π/2 selective Gaussian pulse, a spectral width by a direct dimension, an intensity of the single directional encoding gradient, a first intensity and a second intensity of the two compensation gradients, action durations of the two compensation gradients, a sampling duration of each sampling of the reunion sampling module, an intensity of a decoding gradient, a repeated times 2N of the reunion sampling module, and sampling points, and
the single directional encoding gradient is applied simultaneously with the π/2 selective Gaussian pulse.

6. A method for obtaining a two-dimensional J-resolved Nuclear Magnetic Resonance (NMR) spectrum against an inhomogeneous magnetic field applied along a single direction, wherein the method comprises the following steps:
1) sending a sample tube containing a test sample into a testing cavity of a NMR spectrometer, and applying a sequence of regular one-dimensional hydrogen spectrum to collect a one-dimensional hydrogen spectrum of the test sample, wherein the sequence of the regular one-dimensional hydrogen spectrum is a single-pulse sequence integrated in the NMR spectrometer and comprises a non-selective radio frequency pulse and a signal sampling period;
2) using the single-pulse sequence, measuring a duration of a π/2 non-selective radio frequency pulse required for exciting the test sample, generating a polychromatic pulse by a Fourier encoding technique, and generating a pulse duration and a radio frequency power of the polychromatic pulse according to an experimental requirement to obtain multi-band signals;
3) introducing a designed NMR pulse sequence into the NMR spectrometer, wherein the designed NMR pulse sequence comprises a selective excitation module and a reunion sampling module, setting experimental parameters of the selective excitation module and the reunion sampling module, and sampling data associated with the test sample by a multi-band sampling based on a polychromatic pulse excitation; and
4) after sampling the data, using data post-processing codes, and carrying out data processing to obtain the two-dimensional J-resolved NMR spectrum against the inhomogeneous magnetic field applied along the single direction,
wherein the steps of the data processing are as follows:
(a) collecting odd-numbered data of the data by an odd-numbered sampling module and even-numbered data of the data by an even-numbered sampling module of different quantum levels, separating the odd-numbered data and the even-numbered data in data processing, and separately extracting the odd-numbered data or the even-numbered data for post-processing; and
(b) carrying out a two-dimensional Fourier transform on the odd-numbered data to obtain a piece of the two-dimensional J-resolved NMR spectrum against the inhomogeneous magnetic field applied along the single direction.

7. The method according to claim 6, wherein:
the selective excitation module comprises the polychromatic pulse, a single directional encoding gradient simultaneously applied with the polychromatic pulse, and two compensation gradients,
a direction applied by the single directional encoding gradient and the two compensation gradients is the same as an inhomogeneous direction of the inhomogeneous magnetic field in an actual test, and
the selective excitation module is configured to selectively invert a longitudinal magnetization vector of the test sample into a transverse x-y plane, and to associate a procession frequency of a selected atomic nucleus with a spatial position of the selected atomic nucleus.

8. The method according to claim 6, wherein, in step 4):
after sampling the data, decoding the multi-band signals by the Fourier encoding technique in step 2) to obtain decoded signals before using the data post-processing codes and carrying out the data processing, and
after carrying out the data processing, calibrating and superimposing the decoded signals to obtain the two-dimensional J-resolved NMR spectrum against the inhomogeneous magnetic field applied along the single direction.

9. The method according to claim 2, wherein the sample tube is a 5 mm outside diameter sample tube.
